(19) United States
(12) Patent Application Publication
(10) Pub. No.: US 2025/0384944 A1
(43) Pub. Date: Dec. 18, 2025

(54) PHYSICAL REDUNDANCY AND MAPPING OF ADDRESSES FOR ACCESS LINES IN A MEMORY DEVICE

(71) Applicant: Micron Technology, Inc., Boise, ID (US)

(72) Inventors: Andrea Martinelli, Bergamo (BG) (IT); Christophe Vincent Antoine Laurent, Agrate Brianza (MB) (IT)

(21) Appl. No.: 19/209,532

(22) Filed: May 15, 2025

Related U.S. Application Data
(60) Provisional application No. 63/660,380, filed on Jun. 14, 2024.

(51) Int. Cl. G11C 29/30

(52) U.S. Cl. CPC G11C 29/30

(57) ABSTRACT

Systems, methods, and apparatus for a memory device. In one approach, defective access lines in a memory array are identified during an access phase using a stored list. Physical addresses of the defective access lines are stored in the list. New addresses are received from a host device for incoming access requests. The new addresses are compared to the stored addresses. Based on this comparison, one or more of the new addresses are shifted (e.g., by modifying a logical-to-physical mapping table) to avoid use of the defective access lines. Some of the new addresses are shifted to use redundant access lines.

### RELATED APPLICATIONS

The present application claims priority to Prov. U.S. Pat. App. Ser. No. 63/660,380 filed Jun. 14, 2024, the entire disclosure of which application is hereby incorporated herein by reference.

### FIELD OF THE TECHNOLOGY

At least some embodiments disclosed herein relate to memory devices in general, and more particularly, but not limited to memory devices using physical redundancy.

### BACKGROUND

Memory devices are widely used to store information in various electronic devices such as computers, wireless communication devices, cameras, digital displays, and the like. Information is stored by programming different states of a memory device. For example, binary devices have two states, often denoted by a logic “1” or a logic “0”. In other systems, more than two states may be stored. To access the stored information, a component of the electronic device may read, or sense, the stored state in the memory device. To store information, a component of the electronic device may write, or program, the state in the memory device.

Various types of memory devices exist, including magnetic hard disks, random access memory (RAM), read only memory (ROM), dynamic RAM (DRAM), synchronous dynamic RAM (SDRAM), ferroelectric RAM (FeRAM), magnetic RAM (MRAM), resistive RAM (RRAM), flash memory, phase change memory (PCM), and others. Memory devices may be volatile or non-volatile. Non-volatile memory cells may maintain their stored logic state for extended periods of time even in the absence of an external power source. Volatile memory cells may lose their stored state over time unless they are periodically refreshed by an external power source.

A storage device is an example of a memory device. Typical computer storage devices have controllers that receive data access requests from host computers and perform programmed computing tasks to implement the requests in ways that may be specific to the media and structure configured in the storage devices. In one example, a memory controller manages data stored in memory and communicates with a computer device. In some examples, memory controllers are used in solid state drives for use in mobile devices or laptops, or media used in digital cameras.

Firmware can be used to operate a memory controller for a particular storage device. In one example, when a computer system or device reads data from or writes data to a memory device, it communicates with the memory controller.

Memory devices typically store data in memory cells. In some cases, memory cells exhibit non-uniform, variable electrical characteristics that may originate from various factors including statistical process variations, cycling events (e.g., read or write operations on the memory cells), or a drift (e.g., a change in resistance of a chalcogenide alloy), among others.

In one example, reading a set of data (e.g., a codeword, a page) is carried out by determining a read voltage (e.g., an estimated median of threshold voltages) of memory cells that store the set of data. In some cases, a memory device may include an array of PCM cells arranged in a 3D architecture, such as a cross-point architecture to store the set of data. PCM cells in a cross-point architecture may represent a first logic state (e.g., a logic 1, a SET state) associated with a first set of threshold voltages, or a second logic state (e.g., a logic 0, a RESET state) associated with a second set of threshold voltages. In some cases, data may be stored using encoding (e.g., error correction coding (ECC)) to recover data from errors in the data stored in the memory cells.

For resistance variable memory cells (e.g., PCM cells), one of a number of states (e.g., resistance states) can be set. For example, a single level cell (SLC) may be programmed to one of two states (e.g., logic 1 or 0), which can depend on whether the cell is programmed to a resistance above or below a particular level. As an additional example, various resistance variable memory cells can be programmed to one of multiple different states corresponding to multiple data states, e.g., 10, 01, 00, 11, 111, 101, 100, 1010, 1111, 0101, 0001, etc. Such cells may be referred to as multi state cells, multi-digit cells, and/or multi-level cells (MLCs).

The state of a resistance variable memory cell can be determined (e.g., read) by sensing current through the cell responsive to an applied interrogation voltage. The sensed current, which varies based on the resistance of the cell, can indicate the state of the cell (e.g., the binary data stored by the cell).

A PCM cell, for example, may be programmed to a reset state (amorphous state) or a set state (crystalline state). A reset pulse (e.g., a pulse used to program a cell to a reset state) can include a relatively high current pulse applied to the cell for a relatively short period of time such that the phase change material of the cell melts and rapidly cools, resulting in a relatively small amount of crystallization. Conversely, a set pulse (e.g., a pulse used to program a cell to a set state) can include a relatively lower current pulse applied to the cell for a relatively longer time interval and with a slower quenching speed, which results in an increased crystallization of the phase change material.

A Self-Selecting Memory (SSM) cell, for example, may be programmed to a reset state (high threshold state) or a set state (low threshold state). A set pulse (e.g., a pulse used to program a cell to a set state) can include a pulse of a same polarity of a read pulse applied to the cell such that the resistance-variable material of the cell is set to a low threshold voltage when read in the same polarity as the program pulse. Conversely, a reset pulse (e.g., a pulse used to program a cell to a reset state) can include a pulse of a different polarity, e.g., an opposite polarity than, of a read pulse applied to the cell such that the resistance-variable material of the cell is set to a high threshold voltage when read in the read polarity (e.g., a polarity opposite to the polarity of the program pulse).

A programming signal can be applied to a selected memory cell to program the cell to a target state. A read signal can be applied to a selected memory cell to read the cell (e.g., to determine the state of the cell). The programming signal and the read signal can be current and/or voltage pulses, for example.

### BRIEF DESCRIPTION OF THE DRAWINGS

The embodiments are illustrated by way of example and not limitation in the figures of the accompanying drawings in which like references indicate similar elements.

FIG. 1 shows a memory device that applies read or write voltages for performing read or write operations, in accordance with some embodiments.

FIG. 2 shows a memory device configured with a read manager to select read voltages according to one embodiment.

FIG. 3 shows a memory cell with a bitline driver and a wordline driver configured to apply voltages according to one embodiment.

FIG. 4 shows a memory device including normal and redundant wordlines for accessing memory cells in a memory array, in accordance with some embodiments.

FIG. 5 shows examples of parasitic loads associated with accessing memory cells using access lines.

FIG. 6 shows exemplary electrical distances between a driver/receiver and a memory cell being accessed.

FIG. 7 shows examples of varying memory cell behavior depending on location along an access line.

FIG. 8 shows examples of variations in threshold distributions for memory cells caused by varying electrical distances to memory cells.

FIG. 9 shows an example of re-mapping physical addresses in response to identifying a broken access line, in accordance with some embodiments.

FIG. 10 shows cascaded groups of logic circuitry for shifting addresses from a user (e.g., host device) based on stored broken addresses, in accordance with some embodiments.

FIG. 11 shows an example of a memory device having wordlines stacked in vertical arrangements.

FIG. 12 shows a top view of wordlines extending into two memory arrays of the memory device of FIG. 11.

FIG. 13 shows wordlines in vertical arrangements that use alternating addressing for shifting of addresses in response to identifying defective wordlines, in accordance with some embodiments.

FIG. 14 shows an exemplary three-dimensional memory array structure, in accordance with some embodiments.

FIG. 15 shows a method for shifting addresses after identifying defective access lines, in accordance with some embodiments.

### DETAILED DESCRIPTION

The following disclosure describes various embodiments for memory devices that change addressing used to access memory cells (e.g., memory cells of a flash memory device or a three-dimensional cross-point memory array). At least some embodiments herein relate to memory devices that re-map addressing for access lines (e.g., wordlines or bitlines) used to access memory cells in a memory array. The addressing is re-mapped to use one or more redundant access lines to replace defective access lines.

Various types of non-volatile and volatile memory devices can use re-mapping of addressing as described herein. In one example, the memory cells are arranged in a cross-point architecture. In one example, each memory cell is formed using a single select device, e.g., a selector/memory device, acting both as a select device and a memory device. In one example, the select device includes a chalcogenide material that switches (e.g., snaps) when a sufficient voltage is applied across the memory cell. In other examples, the memory cells are in a three-dimensional NAND flash memory array. In other examples, the memory cells are in a volatile memory device (e.g., DRAM).

The memory device may, for example, store data used by a host device (e.g., a computing device of an autonomous vehicle, or another computing device that accesses data stored in the memory device). In one example, the memory device is a solid-state drive mounted in an electric vehicle.

Physical redundancy (e.g., a memory device having redundant access lines) can be used to repair known physical defects. Examples of such defects include shorted lines, open lines, broken memory cells, and/or broken decoder transistors.

In some prior approaches, when an address is given to a memory array, several lines are activated (e.g., wordlines, bitlines, gate lines, etc.) If one of those lines is known to be defective, it is not activated. Instead, a controller selects another redundant line to replace the defective line.

In such prior approaches, the redundant lines are typically located at a predefined position in the memory array that is significantly different from that of the defective line. Thus, the electrical distance between a driver or sense amplifier and a memory cell being accessed can significantly change. This can result in variations in electrical characteristics and/or behavior that causes errors in reading and/or writing the memory cell.

To address the above and other technical problems, a memory device uses a physical redundancy mechanism to minimize changes in electrical distance (ED) to memory cells when activated. The redundancy lines used to replace defective lines are not predefined as in prior approaches. Once a defect associated with a line is identified, the line is indicated as invalid and deactivated. For example, a controller stores a list of defective lines. A physically close line (e.g., an immediately neighboring line in the memory array, or a line only 2-5 address positions away) is selected to replace it.

In the case of using the immediately neighboring line, which is one address position away, the successive addresses for other lines are shifted by one position. This is done until the address of the last line is shifted to point to the redundant line that has been enabled for use in place of the disabled defective line. This provides a replacement line that is only one address position away from the originally intended, but now determined defective, line. In this approach, a broken line can be replaced by its neighbor line, reducing to a minimum the ED difference between the previously-used natural cells and the now-used redundant cells activated during an access.

In one embodiment, a memory device has access lines to access memory cells in one or more memory arrays. One or more controllers identify a defective access line. The access lines include a redundant access line, and use of the defective access line is replaced by shifting lines to use the redundant access line. The controller(s) stores a broken address of the defective access line. The controller(s) compares the broken address to a mapped physical address for a logical or natural address. Based on the comparison, the controller(s) shifts the mapped physical address (e.g., shift address by +1) of one or more access lines so that the defective access line is no longer used.

In general, one or more logical addresses are received with an access request from a host or user. The logical address(es) is sometimes referred to herein as a natural address(es). For example, an address provided with a read or write access request is a natural address.

A controller can identify or detect a defective access line in various ways. In one embodiment, a defective access line is identified or detected in response to an access request from a host. A logical address (sometimes referred to as a natural address) is received with the access request. The controller, during the access phase, determines that an access line is a defective line based on a successful comparison of the physical mapping for an incoming logical or natural address with a stored address (e.g., one of a list of stored physical addresses for access lines known to be defective). As a result, during a read or write operation, the controller avoids accessing this identified or detected defective line and instead accesses a neighboring line by shifting address mapping for the incoming logical or natural address, as described herein.

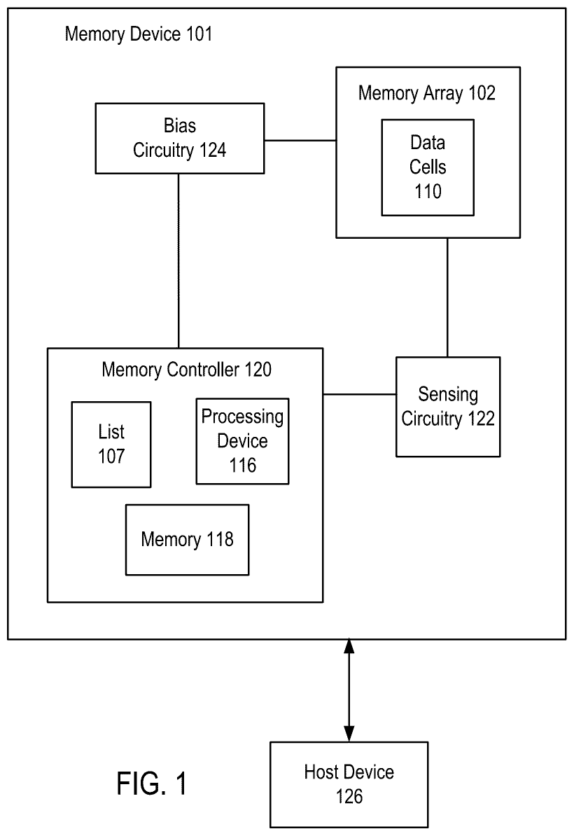

In one embodiment, a controller compares a stored address of defective access lines with an incoming address. An L2P (logical-to-physical) table is used for correspondence between incoming logical addresses (associated with access requests) and physical addresses in a memory array. A list (e.g., list 107 of FIG. 1) is stored of defective line physical addresses and is used by the controller to avoid usage of the defective physical address when using the L2P table. For example, the incoming logical address is re-addressed to the next following physical access line address (e.g., shifted upward by one physical address).

In one embodiment, a memory device includes a memory array having access lines (e.g., each having a physical address corresponding to and mapped to from logical addresses 0, 1, 2, 3). The access lines include at least one redundant access line (e.g., x—not used). For example, FIG. 9 illustrates logical-to-physical mapping of logical addresses 0, 1, 2, 3 to each of four physical access lines. The letter “x” indicates that the corresponding physical access line is not mapped to one of the logical addresses.

In one embodiment, a controller (or by using other approach such as during manufacturing) is used to identify a first access line that is defective (e.g., corresponding to logical address 2). In response to identifying that the first access line is defective, the controller changes logical-to-physical addressing of the first access line to disable use (e.g., from logical address 2 to x—not used), changes logical-to-physical addressing of the redundant access line to enable use (e.g., from x to logical address 3), and changes logical-to-physical addressing of a second access line to continue use at a shifted physical address (e.g., from logical address 3 to logical address 2). The physical access line originally corresponding to logical address 3 will be used for logical address 2 for future access requests (to replace the physically defective line).

In one example, redundancy lines used to replace defective lines are not predefined (meaning that the role/position of any physical line is not pre-assigned). Physically, lines are instead assigned to logical lines progressively (e.g., based on their natural position) until reaching a defective line. The defective line is not mapped to by any logical address (or otherwise assigned for use during memory device operation). Instead, the defective line is skipped and the next physical line in sequence is used. This results in a correspondence table logical-to-physical (L2P) with a step (e.g., +1 physical address) from the physically defective line onward in the memory array.

In one embodiment, the mapping of physical addressing from a logical address to the first access line is changed to map physical addressing for the logical address to an immediately neighboring access line (e.g., physical addressing of the access line used for logical address 2 is shifted by one line to the left or right). In one embodiment, physical addresses for access lines located on one side of the first access line are each shifted by a fixed value (e.g., addresses for lines on the right side shifted by +1, or addresses for lines on the left side shifted by −1). For example, the L2P correspondence used in mapping is increased by +1 (e.g., x2x for addresses before the defective line, and y2 (y+1) from the defective access line onward).

Various advantages are provided by at least some embodiments described herein. For example, electrical mismatches due to different topologies can be reduced as compared to prior defect repair approaches. The same or closely similar electrical distance for all cells addressed in a same read/write access can be maintained. Read/write bandwidth, consumptions, and/or timings can be improved.

In some cases, a memory device that uses re-mapping of access line addressing as described above may include an array of memory cells arranged in a three-dimensional (3D) architecture, such as a cross-point architecture, to store a set of data. The memory cells in a cross-point architecture may, for example, represent a first logic state (e.g., a logic 1, a SET state) associated with a first set of threshold voltages, or a second logic state (e.g., a logic 0, a RESET state) associated with a second set of threshold voltages.

In other embodiments, the memory cells may be arranged in a three-dimensional (3D) vertical architecture. A 3D vertical architecture may include memory cells located at the crossing between a vertical access line (e.g., a bitline pillar), and each one of a plurality of second access lines (e.g., wordlines), formed in horizontal planes or decks parallel to each other.

More generally, an integrated circuit memory cell, such as a memory cell in a cross-point memory or a 3D vertical array, can be programmed to store data by the way of its state at a voltage applied across the memory cell. For example, if a memory cell is configured or programmed in such a state that allows a substantial current to pass the memory cell at a voltage in a predefined voltage region, the memory cell is considered to have been configured or programmed to store a first bit value (e.g., one or zero); and otherwise, the memory cell is storing a second bit value (e.g., zero or one).

Optionally, a memory cell can be configured or programmed to store more than one bit of data by being configured or programmed, for example, to have a threshold voltage in one of more than two separate voltage regions.

In one example, the threshold voltage of a memory cell is such that when the voltage applied across the memory cell is increased to above the threshold voltage, the memory cell switches by changing rapidly or abruptly, snapping (e.g., for a chalcogenide memory cell), or jumping from a non-conductive state to a conductive state. The non-conductive state allows a small leak current to go through the memory cell; and in contrast, the conductive state allows more than a threshold amount of current to go through. Thus, a memory device can use a sensor (e.g., sense amplifier) to detect the change, or determine the conductive/non-conductive state of the memory device at one or more applied voltages, to evaluate or classify the level of the threshold voltage of the memory cell and thus its stored data.

The threshold voltage of a memory cell being configured/programmed to be in different voltage regions can be used to represent different data values stored in the memory cell. For example, the threshold voltage of the memory cell can be programmed to be in any of four predefined voltage regions; and each of the regions can be used to represent the bit values of a different two-bit data item. Thus, when given a two-bit data item, one of the four voltage regions can be selected based on a mapping between two-bit data items and voltage regions; and the threshold voltage of the memory cell can be adjusted, programmed, or configured to be in the selected voltage region to represent or store the given two-bit data item. To retrieve, determine, or read the data item from the memory cell, one or more read voltages can be applied across the memory cell to determine which of the four voltage regions contain the threshold voltage of the memory cell. The identification of the voltage region that contains the threshold voltage of the memory cell provides the two-bit data item that has been stored, programmed, or written into the memory cell.

For example, a memory cell can be configured or programmed to store a one-bit data item in a Single Level Cell (SLC) mode, or a two-bit data item in a Multi-Level Cell (MLC) mode, or a three-bit data item in a Triple Level Cell (TLC) mode, or a four-bit data item in Quad-Level Cell (QLC) mode.

FIG. 1 shows a memory device 101 that applies read or write voltages for performing read or write operations, in accordance with some embodiments. Memory device 101 includes a memory array 102 having memory or data cells 110. The data cells 110 generally store data (e.g., user data stored for host device 126). For example, codewords or blocks can be stored in data cells 110.

When performing a read or write operation, bias circuitry 124 applies voltages to data cells. In one example, bias circuitry 124 includes wordline and bitline drivers (not shown) to bias wordlines and bitlines of memory array 102.

Various access lines (not shown) such as wordlines and bitlines are used to access data cells 110. Memory controller 120 uses bias circuitry 124 to apply various voltages and/or currents to the access lines.

In various embodiments, controller 120 identifies one or more of the access lines that are defective. Alternatively, controller 120 can identify other defects associated with access to one or more memory cells. For example, a memory cell itself may be defective.

Controller 120 stores a list 107 of access lines that are defective. In one example, list 107 includes addresses corresponding to defective access lines. In other embodiments, list 107 includes a list of addresses and/or other location data associated with defects in memory array 102.

In response to identifying defects in access lines or otherwise as discussed above, controller 120 changes addressing of access lines in memory array 102 so that any access line or address associated with a defect is no longer used. Instead, addresses of access lines are shifted or otherwise changed so that one or more redundant access lines are used (e.g., as described above).

In one embodiment, controller 120 receives addresses from host device 126. In one example, the addresses are associated with access requests. Controller 120 compares received addresses to addresses stored in list 107. Based on this comparison, one or more addresses of access lines in memory array 102 are changed. In one example, the addresses are changed by shifting the address of each access line by one position either positively or negatively. In one example, received addresses are logical addresses (e.g., natural addresses) for incoming read or write requests. The addresses stored in list 107 are addresses of defective physical lines in memory array 102. Logical addresses provided by host device 126 with the read or write requests go through an L2P table and are transformed into a physical address for comparison with addresses in list 107.

Sensing circuitry 122 is used to read data cells 110. In one example, sensing circuitry 122 includes sense amplifiers for sensing a characteristic associated with memory cells of the memory array 102. The characteristic can be, for example, a voltage and/or current associated with a selected memory cell.

Controller 120 determines, for example, an initial read voltage to use when reading (e.g., user data) from data cells 110. In one example, bias circuitry 124 applies this initial read voltage to data cells 110 when starting a read. In one example, bias circuitry 124 jumps to this initial read voltage during a read of data cells 110.

Memory controller 120 includes one or more processing devices 116 and memory 118. In one example, memory 118 stores firmware executed by processing device 116 to select and apply the read voltages.

Memory controller 120 can use bias circuitry 124 to generate voltages for applying read and other voltages (e.g., initial read and read retry). Bias circuitry 124 can also generate voltages for applying write voltages to data cells 110 as part of programming operations. Bias circuitry 124 may be used to generate read voltages for read operations performed on memory array 102 (e.g., in response to a read command from host device 126).

Sensing circuitry 122 can be used to sense a state of each memory cell in memory array 102. In one example, sensing circuitry 122 includes sense amplifiers used to detect a current caused by applying various voltages to memory cells in memory array 102. In one example, bias circuitry 124 applies a read voltage to data cells 110. Sensing circuitry 122 senses a current associated with each of the data cells 110 caused by applying the read voltage.

In one example, if sensing circuitry 122 determines that the current for a memory cell is greater than a fixed threshold (e.g., a predetermined level of current), then memory controller 120 determines that the memory cell has switched (e.g., snapped).

In one embodiment, memory controller 120 receives a write command from a host device 126. The write command is accompanied by data (e.g., user data of a user of host device 126) to be written to memory array 102. In response to receiving the write command, controller 120 initiates a programming operation.

Error results from ECC of read data can be used when selecting the read voltage (e.g., a read retry voltage). For example, the stored data and/or ECC results can be provided as inputs to a machine learning model (e.g., artificial neural network) to provide an output of a voltage to use for read retry.

In one example, controller 120 may use write voltages (e.g., write pulses) to write a logic state to a memory cell, such as data cell 110 during a write or programming operation. The write pulses may be applied by providing a first voltage to a bitline and providing a second voltage to a wordline to select the memory cell. Circuits coupled to access lines to which memory cells may be coupled may be used to provide the write voltages (e.g., access line drivers included in decoder circuits). The circuits may be controlled by internal control signals provided by a control logic (e.g., controller 120). The resulting voltage applied to the memory cell is the difference between the first and second voltages. The write pulses may be the same duration as read pulses in some embodiments. In some embodiments the duration is 10-50 ns. In some embodiments, the duration is 1-100 ns. In some embodiments, the duration is 1 ns to 1 microsecond. Writing to the memory cell may take the same time as reading the memory cell in some embodiments.

In one example, the polarity of the read or write pulses may be either a first polarity or a second polarity. For example, a write pulse may apply a voltage to a memory cell in a first polarity (e.g., bitline at 6V and wordline at 0V).

In one example, circuits coupled to access lines to which memory cells may be coupled are used to provide read pulses (e.g., access line drivers included in decoder circuits). The circuits may be controlled by internal control signals provided by a control logic (e.g., controller 120). A read voltage or pulse may be a voltage applied to a memory cell for a period of time (e.g., 10-50 ns, 1-100 ns, 1 ns to 1 microsecond). In some embodiments, the read pulse may be a square pulse. In some embodiments, the read pulse may be a ramp, that is, a linearly-increasing voltage may be applied across the memory cell.

In one example, after being accessed (e.g., selected), a memory cell may be read, or sensed, by a sense component (e.g., sensing circuitry 122) to determine the stored state of the memory cell. For example, a voltage may be applied to the memory cell (using a wordline and bitline) and the presence of a resulting current may depend on the applied voltage and the threshold voltage of the memory cell. In some cases, more than one voltage may be applied. Additionally, if an applied voltage does not result in current flow, other voltages may be applied until a current is detected by the sense component. By assessing the voltage that resulted in current flow, the stored logic state of the memory cell may be determined. In some cases, the voltage may be ramped up in magnitude until a current flow is detected (e.g., a memory cell turns on, switches on, conducts current, or becomes activated). In other cases, predetermined voltages may be applied sequentially until a current is detected. Likewise, a current may be applied to a memory cell, and the magnitude of the voltage to create the current may depend on the electrical resistance or the threshold voltage of the memory cell.

In some cases, the memory cell (e.g., a PCM cell) includes a material that changes its crystallographic configuration (e.g., between a crystalline phase and an amorphous phase), which in turn, determines a threshold voltage of the memory cell to store information. In other cases, the memory cell includes a material that remains in a crystallographic configuration (e.g., an amorphous phase) that may exhibit variable threshold voltages to store information.

The sense component may include various transistors or amplifiers in order to detect and amplify a difference in the signals. The detected logic state of the memory cell may then be output through a column decoder as output. In some cases, the sense component may be part of a column decoder or a row decoder.

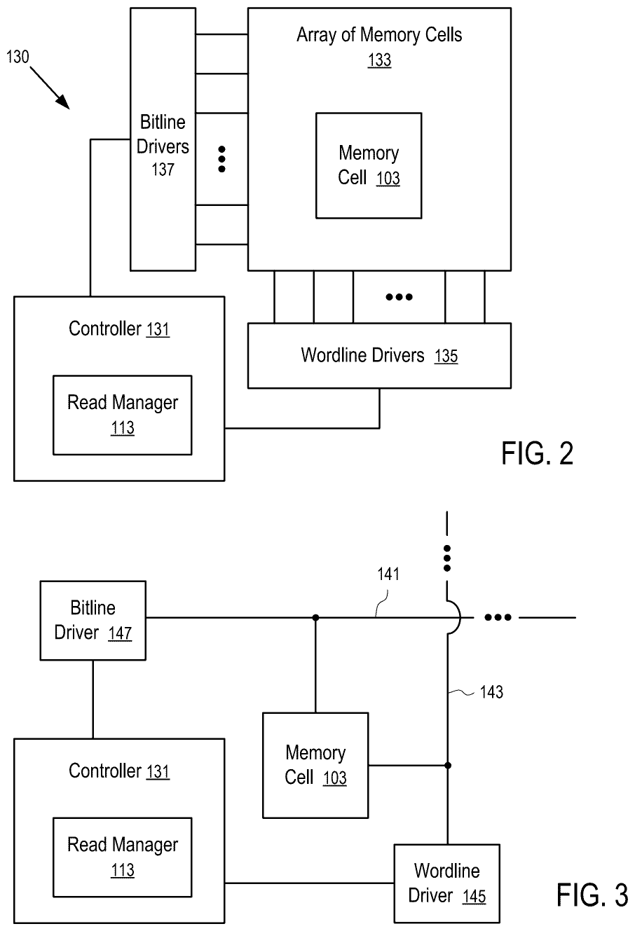

FIG. 2 shows a memory device 130 configured with a read manager 113 to select read voltages according to one embodiment. Memory device 130 is an example of memory device 101. In FIG. 2, the memory device 130 includes an array 133 of memory cells, such as a memory cell 103. Memory cell 103 is an example of data cell 110.

In one example, an array 133 can be referred to as a tile; and a memory device (e.g., 130) can have one or more tiles. Different tiles can be operated in parallel in a memory device (e.g., 130).

For example, the memory device 130 illustrated in FIG. 2 can have a cross-point memory having at least the array 133 of memory cells (e.g., 103). In another example, the memory device 130 illustrated in FIG. 2 can have a 3D vertical architecture having at least the array 133 of memory cells (e.g., 103).

In some implementations, the cross-point memory uses a memory cell 103 that has an element (e.g., a sole element) acting both as a selector device and a memory device. For example, the memory cell 103 can use a single piece of alloy with variable threshold capability. The read/write operations of such a memory cell 103 can be based on thresholding the memory cell 103 while inhibiting other cells in sub-threshold bias, in a way similar to the read/write operations for a memory cell having a first element acting as a selector device and a second element acting as a phase-change memory device that are stacked together as a column. A selector device usable to store information can be referred to as a selector/memory device.

The memory device 130 of FIG. 2 includes a controller 131 that operates bitline drivers 137 and wordline drivers 135 to access the individual memory cells (e.g., 103) in the array 133.

For example, each memory cell (e.g., 103) in the array 133 can be accessed via voltages driven by a pair of a bitline driver 147 and a wordline driver 145, as illustrated in FIG. 3.

The controller 131 includes a read manager 113 configured to implement a process that determines one or more read voltages for reading data cells. The read manager 113 can be implemented, for example, via logic circuits and/or microcode/instructions. For example, during a read retry, the read manager 113 uses a read voltage having a magnitude larger than a read voltage previously used to read the memory cell (e.g., 103). The increase in the read voltage can be based on reading pattern cells (e.g., counting snaps of pattern cells). The read voltage with the increased magnitude applied to the memory cell (e.g., 103) can be sufficient to obtain the error free data from the memory cell (e.g., 103).

FIG. 3 shows a memory cell 103 with a bitline driver 147 and a wordline driver 145 configured to apply voltages (e.g., ramps) according to one embodiment. For example, the memory cell 103 can be a typical memory cell 103 in the memory cell array 133 of FIG. 2.

The bitline driver 147 and the wordline driver 145 of FIG. 3 are controlled by the read manager 113 of the controller 131 to selectively apply one or more voltages to the memory cell 103. The bitline driver 147 and the wordline driver 145 can apply voltages of different polarities on the memory cell 103.

For example, in applying one polarity of voltage (e.g., positive polarity), the bitline driver 147 drives a positive voltage relative to the ground on a bitline 141 connected to a row of memory cells in the array 133; and the wordline driver 145 drives a negative voltage relative to the ground on a wordline 143 connected to a column of memory cells in the array 133.

In applying the opposite polarity of voltage (e.g., negative polarity), the bitline driver 147 drives a negative voltage on the bitline 141; and the wordline driver 145 drives a positive voltage on the wordline 143.

The memory cell 103 is in both the row connected to the bitline 141 and the column connected to the wordline 143. Thus, the memory cell 103 is subjected to the voltage difference between the voltage driven by the bitline driver 147 on the bitline 141 and the voltage driven by the wordline driver 145 on the wordline 143.

In general, when the voltage driven by the bitline driver 147 is higher than the voltage driven by the wordline driver 145, the memory cell 103 is subjected to a voltage in one polarity (e.g., positive polarity); and when the voltage driven by the bitline driver 147 is lower than the voltage driven by the wordline driver 145, the memory cell 103 is subjected to a voltage in the opposite polarity (e.g., negative polarity).

In some implementations, the memory cell 103 is a self-selecting memory cell implemented using a selector/memory device. The selector/memory device has a chalcogenide (e.g., chalcogenide material and/or chalcogenide alloy). For example, the chalcogenide material can include a chalcogenide glass such as, for example, an alloy of selenium (Se), tellurium (Te), arsenic (As), antimony (Sb), carbon (C), germanium (Ge), and silicon (Si). A chalcogenide material can primarily have selenium (Se), arsenic (As), and germanium (Ge) and be referred to as SAG-alloy. SAG-alloy can include silicon (Si) and be referred to as SiSAG-alloy. In some embodiments, the chalcogenide glass can include additional elements such as hydrogen (H), oxygen (O), nitrogen (N), chlorine (CI), or fluorine (F), each in atomic or molecular forms.

The selector/memory device has a top side and a bottom side. A top electrode is formed on the top side of the selector/memory device for connecting to a bitline 141; and a bottom electrode is formed on the bottom side of the selector/memory device for connecting to a wordline 143. For example, the top and bottom electrodes can be formed of a carbon material. For example, a chalcogenide material of the memory cell 103 can take the form of a crystalline atomic configuration or an amorphous atomic configuration. The threshold voltage of the memory cell 103 can be dependent on the ratio of the material in the crystalline configuration and the material of the amorphous configuration in the memory cell 103. The ratio can change under various conditions (e.g., having currents of different magnitudes and directions going through the memory cell 103).

A self-selecting memory cell 103, having a selector/memory device, can be programmed to have a threshold voltage window. The threshold voltage window can be created by applying programming pulses with opposite polarity to the selector/memory device. For example, the memory cell 103 can be biased to have a positive voltage difference between two sides of the selector/memory device and alternatively, or to have a negative voltage difference between the same two sides of the selector/memory device. When the positive voltage difference is considered in positive polarity, the negative voltage difference is considered in negative polarity that is opposite to the positive polarity. Reading can be performed with a given/fixed polarity. When programmed, the memory cell has a low threshold (e.g., lower than the cell that has been reset, or a cell that has been programmed to have a high threshold), such that during a read operation, the read voltage can cause a programmed cell to snap and thus become conductive while a reset cell remains non-conductive.

For example, to program the voltage threshold of the memory cell 103, the bitline driver 147 and the wordline driver 145 can drive a pulse of voltage onto the memory cell 103 in one polarity (e.g., positive polarity) to snap the memory cell 103 such that the memory cell 103 is in a conductive state. While the memory cell 103 is conductive, the bitline driver 147 and the wordline driver 145 continue driving the programming pulse to change the threshold voltage of the memory cell 103 towards a voltage region that represents the data or bit value(s) to be stored in the memory cell 103.

The controller 131 can be configured in an integrated circuit having a plurality of decks of memory cells. Each deck can be sandwiched between a layer of bitlines, a layer of wordlines; and the memory cells in the deck can be arranged in an array 133. A deck can have one or more arrays or tiles. Adjacent decks of memory cells may share a layer of bitlines (e.g., 141) or a layer of wordlines (e.g., 143). Bitlines are arranged to run in parallel in their layer in one direction; and the wordlines are arranged to run in parallel in their layer in another direction orthogonal to the direction of the bitlines. Each of the bitlines is connected to a row of memory cells in the array; and each of the wordlines is connected to a column of memory cells in the array. Bitline drivers 137 are connected to bitlines in the decks; and wordline drivers 135 are connected to wordlines in the decks. Thus, a typical memory cell 103 is connected to a bitline driver 147 and a wordline driver 145.

The threshold voltage of a typically memory cell 103 is configured to be sufficiently high such that when only one of its bitline driver 147 and wordline driver 145 drives a voltage in either polarity while the other voltage driver holds the respective line to the ground, the magnitude of the voltage applied across the memory cell 103 is insufficient to cause the memory cell 103 to become conductive. Thus, addressing the memory cell 103 can be performed via both of its bitline driver 147 and wordline driver 145 driving a voltage in opposite polarity relative to the ground for operating/selecting the memory cell 103. Other memory cells connected to the same wordline driver 145 can be de-selected by their respective bitline drivers holding the respective bitlines to the ground; and other memory cells connected to the same bitline driver can be de-selected by their respective wordline drives holding the respective wordlines to the ground.

A group of memory cells (e.g., 103) connected to a common wordline driver 145 can be selected for parallel operation by their respective bitline drivers (e.g., 147) driving up the magnitude of voltages in one polarity while the wordline driver 145 is also driving up the magnitude of a voltage in the opposite polarity. Similarly, a group of memory cells connected to a common bitline driver 147 can be selected for parallel operation by their respective wordline drivers (e.g., 145) driving voltages in one polarity while the bitline driver 147 is also driving a voltage in the opposite polarity.

At least some examples are disclosed herein in reference to a cross-point memory having self-selecting memory cells. Other types of memory cells and/or memory can also be used. For example, memory cells each having a selector device and a phase-change memory device and/or flash memory cells can also be used in at least some embodiments. Additionally or alternatively, the memory can have a different architecture, such as a 3D vertical architecture.

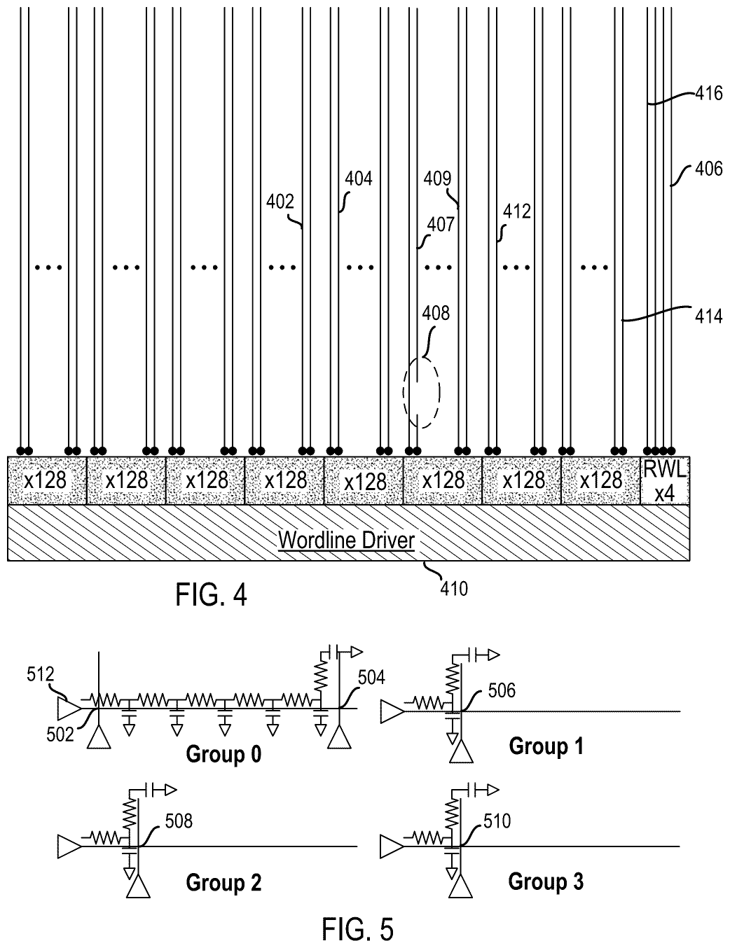

FIG. 4 shows a memory device including normal and redundant wordlines for accessing memory cells in a memory array, in accordance with some embodiments. Normal wordlines include, for example lines 402, 404. Redundant wordlines include, for example, lines 406, 416. Wordline driver(s) 410 applies voltages to the normal wordlines. Wordline driver 410 applies voltages to any of the redundant wordlines that have been configured for usage.

In one example, the normal and redundant wordlines are metal lines inside a memory array. The default normal wordlines are arranged in groups of 128 lines (e.g., corresponding to the decoding of seven address bits).

In prior approaches, in response to identifying a defect in a line, one of the redundant lines is used as a replacement. For example, line 407 has a break 408. Redundant line 416 is used to replace line 407. However, the electrical distance to the memory cell can change significantly based on this replacement. This is because the positions of the redundant lines is fixed or predefined.

In one example of a legacy memory approach, additional lines are built at the end of an array block, as illustrated. In one example, the array block is a physical partition inside a memory array such as a plane or a tile. These lines are specifically designated to be redundancy lines, and have a specific address decoding mechanism. These lines are at specific locations (e.g., at the end, beginning, or in the middle).

In contrast, according to various embodiments as described herein, in response to identifying defective line 407, a controller or other logic shifts the address of line 407 to that of the immediately neighboring wordline. This corresponds to a shift in address of plus one (+1). Addresses for other wordlines (e.g., 409, 412, 414) to the right of line 407 are also shifted by plus one. In the case of line 414, its address is shifted from line 414 to redundant line 416. The addresses of lines 402, 404 are not shifted because these lines are to the left of line 407, and the redundant lines are to the right of line 407.

The defective line 407 can be identified or detected in various ways. In one embodiment, a wordline is tested and evaluated as being defective (e.g., during manufacturing and testing in a fabrication facility). In this case, the wordline is marked as defective, its address is stored and the wordline is not used.

In one embodiment, the defective line 407 is identified or detected by comparing its physical address to a list (e.g., table) of physical addresses of defective wordlines that is used to re-address memory access in the array. This identification occurs during device operation when an access request is received.

In one example, identifying a defective line is performed either during a testing phase (then its address is stored) and/or during access (by positive comparison with a stored address of a defective line, then re-addressing is effected). Physical addressing is shifted, for example, by +1 (see, e.g., FIG. 9).

More generally, a logical address x is normally mapped to a physical address x (e.g., in the absence of defective lines); if a physical line y is identified to be defective, logical addresses z (>y) are mapped to physical addresses z+1 (e.g., y changes to y+1, y+1 changes to y+2, etc.), therefore implementing the shift in physical address of plus one (+1).

FIG. 5 shows examples of parasitic loads associated with accessing memory cells using access lines. Memory cells 502, 506, 508, 510 are located at the intersection of two access lines, as illustrated. Various groups of memory cells are illustrated. In this example, a defect is identified that is associated with memory cell 502.

In the prior legacy memory approach, memory cell 502 is replaced by memory cell 504 due to identification of the defect. However, in this prior approach, memory cell 504 is located at a significantly greater electrical distance from driver 512 then the electrical distance of memory cell 502 from driver 512. As described above, this change in electrical distance can cause errors in read or write operations for memory cell 504. This problem is caused by the replacement line being far from the broken line. In some technologies, this long distance may be problematic. In particular, memories that use a current flowing through the memory cell can be severely affected by this increased parasitic load.

As illustrated, parasitic resistance and capacitance loads are associated with the access lines. Groups 1, 2, 3 each have negligible IR drop due to current flow. But for group 0, the replacement memory cell 504 sees a significantly different polarization during operation. Various embodiments as described herein minimize this problem of electrical distance change by using replacement memory cells that are close to the defective memory cell.

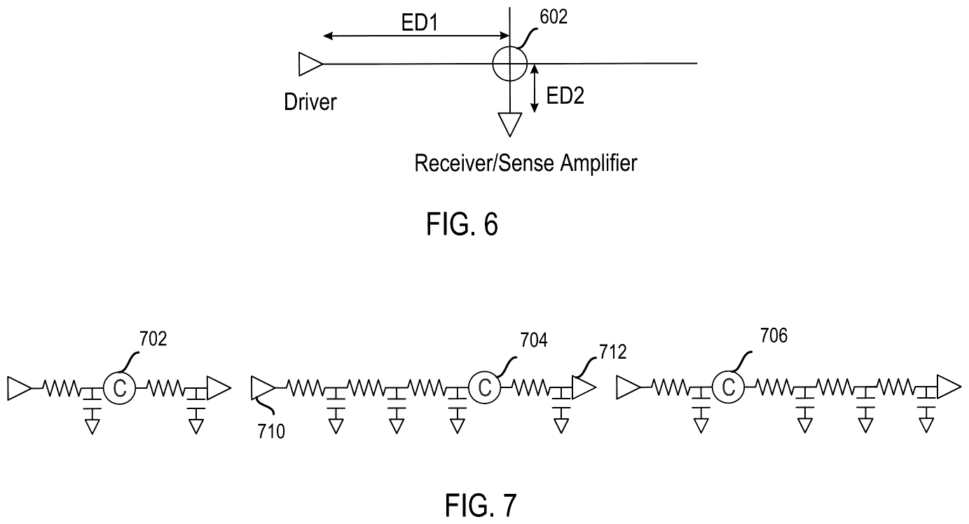

FIG. 6 shows exemplary electrical distances between a driver/receiver and a memory cell 602 being accessed. The electrical distance (ED) is a measure of the length of the access lines seen by memory cell 602. The electrical distance corresponds to the distances between the drivers/receiver and the selected memory cell.

The electrical distance is generally a representation of the electrical resistance of the lines between the driver and the receiver. Electrical distance can have significant effect for certain memory technologies, especially where the involved current is higher and for cross-point memories.

The total electrical distance is a function of the sums of electrical distances associated with each access line (ED1, ED2 as illustrated). For some technologies, the total electrical distance may simply be ED=ED1+ED2.

Electrical distance is a way to represent parasitics (e.g., parasitic resistance due to current flowing through the lines). The resistance is directly linked to the length of the lines that are involved.

FIG. 7 shows examples of varying memory cell behavior depending on location along an access line. Memory cells 702, 704, 706 are located at different positions on an access line between a driver 710 and sense amplifier 712. This causes different resistances between the memory cell and the driver or sense amplifier. The memory cells may not behave exactly in the same way, depending on those resistances and their position.

In some types of memory, it is desirable that all memory cells behave in the same way during an access (e.g., read or write). For example, as shown in FIG. 5, groups 1, 2 and 3 have the same resistive path and are likely to behave in the same way, while group 0 will likely be differently (e.g., cell has a different threshold).

It is preferred to have all the cells during an access behave in the same way. Various embodiments as described herein enable having the same or more closely similar resistive paths (same electrical distances) to, for example, improve uniformity of threshold distributions for memory cells being accessed.

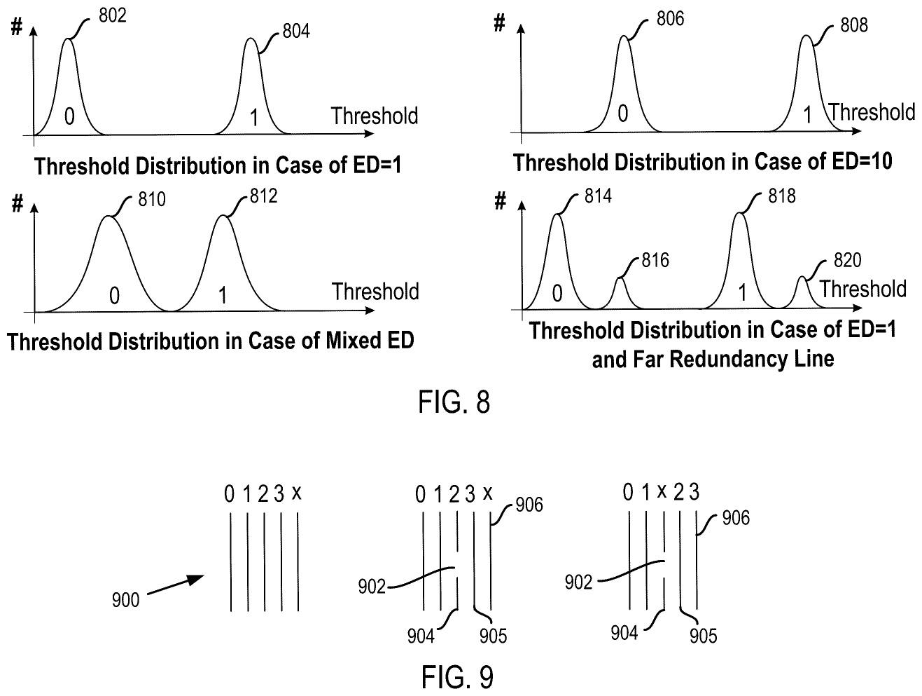

FIG. 8 shows examples of variations in threshold distributions for memory cells caused by varying electrical distances to memory cells. Threshold distributions are generally more uniform with good separation when all memory cells being accessed have the same or similar electrical distance. The number (#) of cells is on the vertical axis.

For example, distributions 802, 804 are tight with significant separation between two different logic states of zero and one. This is due to the electrical distance being equal to one for all memory cells. Similarly, distributions 806, 808 are tight and uniform even though the threshold values are shifted as compared to distributions 802, 804. The uniformity is caused by the electrical distance to memory cells being the same or similar (ED=10). In each case, there is significant margin for read/write operations.

In contrast, distributions 810, 812 correspond to memory cells having a mix of different electrical distances. As compared to above, distributions 810, 812 are wider and read/write margin is reduced. This problem is associated with prior legacy memory redundancy approaches, as described above.

Similarly, distributions 816, 820 correspond to memory cells on redundancy lines that are far from the original normal default lines. Distributions 814, 816 and 818, 820 are wider and less uniform due to this change in electrical distance. Read/write margin is reduced as a result. This problem is also associated with prior legacy approaches. These problems can be avoided by various embodiments as described herein that implement redundancy with minimal changes in electrical distance by shifting addresses.

FIG. 9 shows an example of re-mapping physical addresses in response to identifying a broken access line, in accordance with some embodiments. Access lines 900 in an original default operating state have physical addresses 0, 1, 2, 3 as shown. The symbol “x” indicates a redundant line that is not used. Access line 904 is identified as being defective due to a broken line 902. In response to identifying this defect, a controller changes addressing for the access lines so that redundant line 906 is used, and use of line 904 is ended. In this way, the total number of lines remains unchanged. In one example, controller 120 changes the addressing based on defects identified in list 107.

The controller changes the decoding of the addresses to implement use of redundant line 906. The controller generally shifts addresses by one position to the right due to the addition of one redundant line. For example, the address 2 for line 904 is re-mapped to line 905. The address 3 for line 905 is re-mapped to line 906. This creates a hole in the addressing that is occupied by the defective line. In general, the controller does re-mapping of multiple lines to shift them. For example, a typical array block has thousands of lines, any of which can be shifted as appropriate based on identified defects.

In this case, the controller moves all the lines that are on the right of the defective line 904. This is different from the legacy memory approach described above in which a controller merely replaces the defective line 904 with the line 906. It should be noted that in other cases, the controller can move all lines that are on the left of the defective line 904 when redundant lines are located to the left of the defective line 904.

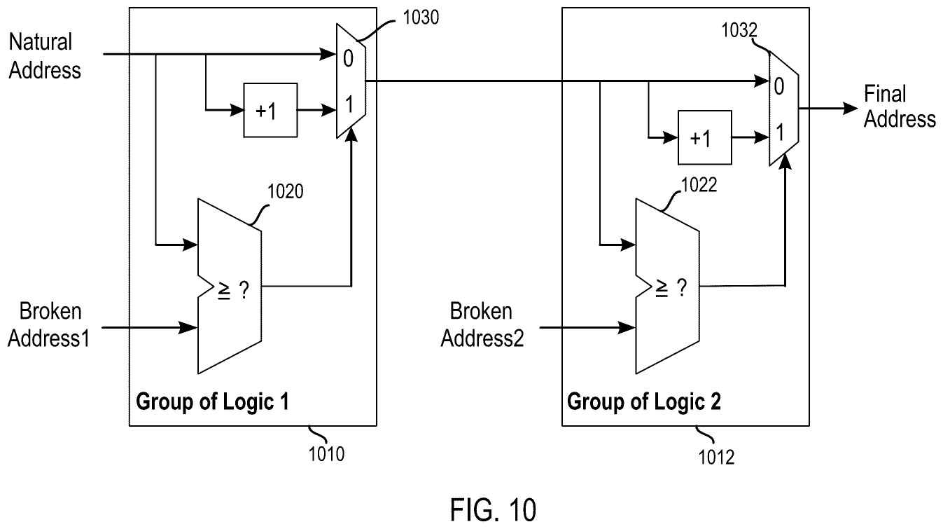

FIG. 10 shows cascaded groups of logic circuitry for shifting addresses from a user (e.g., host device) based on stored broken addresses, in accordance with some embodiments. In one example, the groups of logic circuitry is implemented in a memory device 101. In one example, this logic is implemented by memory controller 120 at least in part by firmware.

Logic groups 1010, 1012 are cascaded. A number of logic groups used corresponds to a number of redundant lines to be used. The illustrated implementation is for a group of access lines with two redundant access lines. If more redundant lines are available, additional similar groups of logic are cascaded together.

Broken addresses 1, 2 correspond to access lines identified as defective. This logic circuitry decodes addresses to change addressing based on identified defects. Each natural address (e.g., an address provided with the read or write access requests) is compared to broken address 1 using comparator 1020. If the natural address is greater than or equal to the broken address 1, then the natural address is shifted by +1 using multiplexer 1030. The output of multiplexer 1030 is the shifted address.

The shifted address is then compared to broken address 2 using comparator 1022. If the shifted address is greater than or equal to the broken address 2, then the shifted address is increased by +1 using multiplexer 1032. Thus, the final address can be shifted up to two times (corresponding to up to two defective lines), depending on the comparisons above.

In one example, this logic circuitry shifts the addresses of wordlines. The addresses of the two broken lines are stored (e.g., in list 107). The natural address comes from the user. Broken address 1 is lower than broken address 2. The lower address is stored first in order for this logic implementation. In general, the broken addresses are stored in ascending order in this implementation. These stored addresses are physical addresses. This logic can be implemented by logic circuitry or controller firmware.

If the natural address is less than the broken address 1, then multiplexer 1030 outputs the natural address; similarly, when the address output from multiplexer 1030 is less than broken address 2, then multiplexer 1032 outputs it unchanged. In the case of less than two defective lines, the final address will be the same as the natural address or just shifted by +1.

In an alternative embodiment, if the addresses were placed in the other order, the logic would implement a minus one approach. For example, the redundant rows would be 0 and 1. Also, in some embodiments, the adjustment can be greater than one. For example, this may occur when repairing multiple lines.

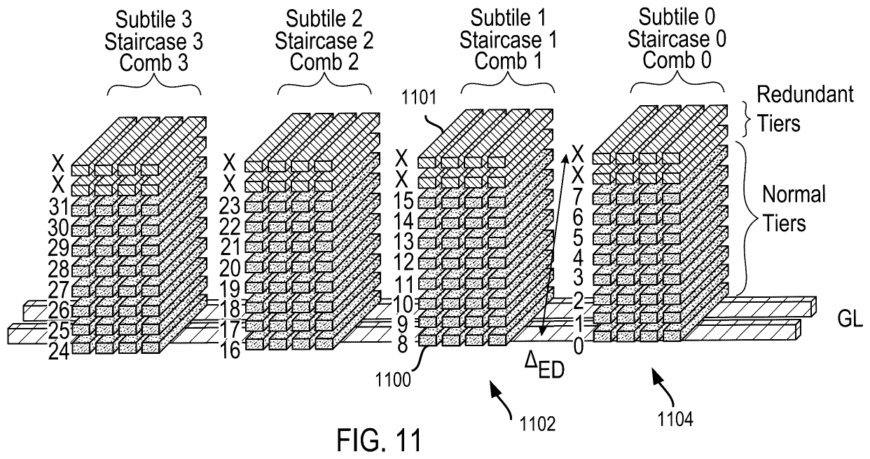

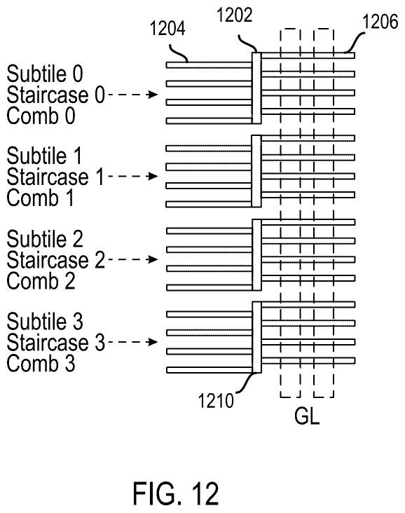

FIG. 11 shows an example of a memory device having wordlines 1100, 1101 stacked in vertical arrangements 1102, 1104. The memory device can be any of various types of vertical devices. For example, it can be a three-dimensional (3D) NAND or cross-point memory device. In the Z vertical dimension, access lines are stacked in tiers. The illustrated numbers (e.g., 0, 1, 2, . . . 7) indicate the address number of the tier. This adds a third dimension to the electrical distance for each memory cell (e.g., ED1+ED2+ED3). Bitline pillars (not shown) extend vertically in the array, and memory cells are positioned at crossings of wordlines and bitline pillars. Gate lines are indicated by “GL” and selectively couple bitline pillars to digit lines (not shown).

As illustrated, the natural tiers addressing is increasing from bottom to top in each arrangement. Thus, this address localization to each arrangement limits shifting of addresses in response to defects to a single vertical arrangement. For example, when using only two redundant tiers (x, x) in an arrangement, a maximum of two repairs in that same arrangement are possible while still maintaining a reduced ED difference.

If shifting of addressing were to go across more than one arrangement, then the delta in electrical distance from a tier at the top of an arrangement to a tier at the bottom of an arrangement would be large due to the big change in vertical physical distance. This results from the vertically increasing addresses as illustrated (addresses increasing going up vertically in each of the arrangements).

FIG. 12 shows a top view of wordlines extending into two memory arrays of the memory device of FIG. 11. Wordlines (e.g., 1202, 1210) are illustrated for each of several arrangements. For example, wordline 1202 has fingers 1204 extending into a left array (not shown) and fingers 1206 extending into a right array. “GL” indicates gate lines for selectively driving bitline pillars vertically extending out of the page (not shown in the drawing), with cells formed at cross-points of wordlines and bitline pillars at each tier. For example, four fingers are addressed in parallel by a wordline for each array. The wordlines are driven, for example, in the middle between the left and right arrays.

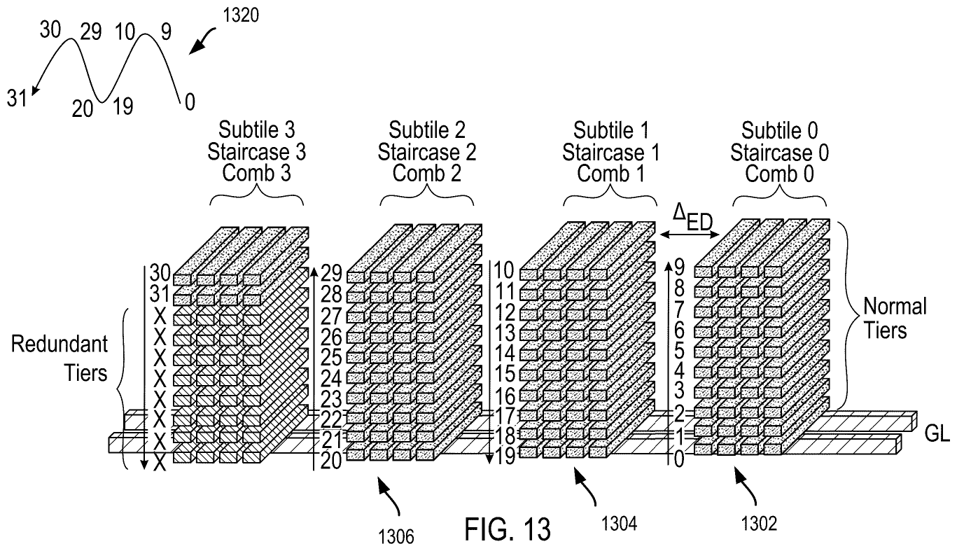

FIG. 13 shows wordlines in vertical arrangements that use alternating addressing for shifting of addresses in response to identifying defective wordlines, in accordance with some embodiments. Wordlines are arranged in vertical tiers for various arrangements 1302, 1304, 1306. Redundant tiers are all located together.

A snaking addressing is used to reduce the electrical distance between every consecutive address. This addressing is illustrated in snake-like shape 1320. Addresses of tiers increase in a vertical upward direction from tier 0 to tier 9. Then, addresses increase in a vertical downward direction from tier 10 to tier 19. Then, addresses again increase in a vertical upward direction from tier 20 to tier 29. This can continue for any desired extent of the memory device.

This new alternating addressing provides better flexibility in the number of defects per vertical arrangement that can be repaired, and can reduce the ED difference to 1 address position. In one example, it is possible to correct more than two errors in the same vertical arrangement.

It is continuous vertically alternating numbering of tiers that reduces the electrical distance when shifting addresses of tiers up or down. For example, shifting addresses from tier 9 to tier 10 is a small change in electrical distance as compared to the approach of FIG. 11. For example, more than two errors can be corrected because addresses are shifted all along the snake through multiple arrangements.

Advantages of the snaking addressing include more flexibility and/or choice to correct defects in the alternating address area. For example, three or more defects in the same vertical arrangement can be corrected with a minimal ED impact.

In various embodiments, when a defect is identified, a controller uses the closest line to the defect whether it is a shift right or left.

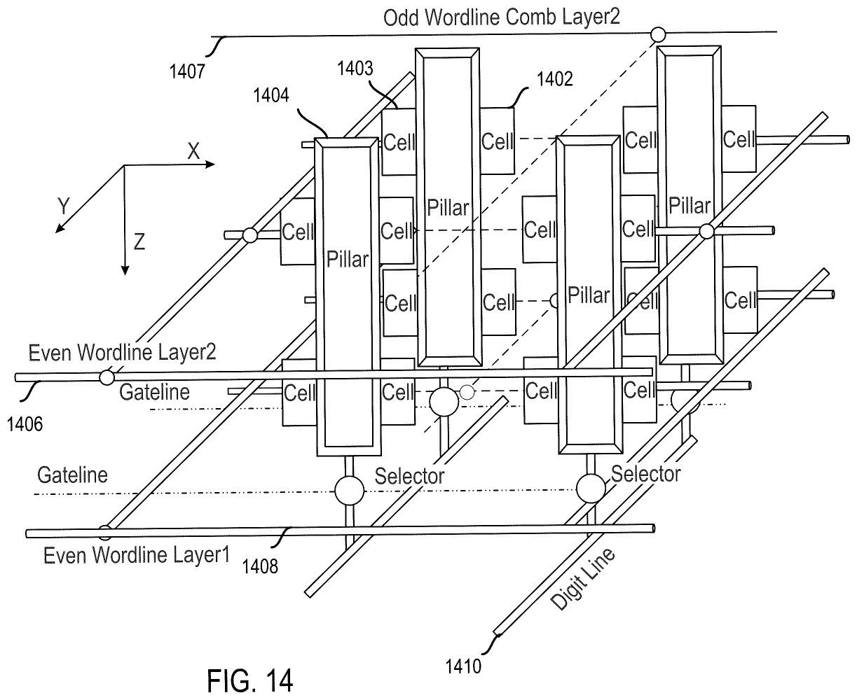

FIG. 14 shows an exemplary three-dimensional memory array structure, in accordance with some embodiments. The illustrated three-dimensional memory array structure is an example of memory array 102.

The memory array and memory cells described herein are not limited to use in a planar architecture (e.g., with cells at crossing of wordlines (WLs) and bitlines (BLs) on different levels). Instead, the approach also can be used for vertical architectures (e.g., vertical BL pillars crossing horizontal WL planes).

An example of a vertical architecture that can be used with embodiments described in this disclosure is illustrated in FIG. 14. As illustrated, a memory array includes memory cells 1402, 1403. Each memory cell 1402, 1403 can be selected using a wordline (e.g., 1406, 1407, or 1408) and a digit line (e.g., 1410). Wordlines 1406, 1407, or 1408 are examples of wordlines 1100 and 1101 of FIG. 11. Memory cells 1402, 1403 are an example of data cells 110 of FIG. 1.

In one embodiment, each wordline extends in one of a plurality of horizontal planes of wordlines 1406, 1407, 1408 stacked vertically above a semiconductor substrate (not shown). Each digit line or bitline (e.g., 1410) includes a bitline pillar 1404. Each pillar 1404 extends vertically away from the semiconductor substrate. Each memory cell 1402, 1403 is located on sides of one of pillars 1404.

In one embodiment, the memory array has a vertical array architecture comprising vertical bitlines (e.g., vertical pillars 1404) or digit lines intersecting a plurality of horizontal decks of wordlines (e.g., even wordlines 1406 and odd wordlines 1407). Each deck is configured as two interdigitated wordline combs so that each bitline or digit line forms two cells 1402, 1403 at each of the decks. In one example, even wordlines 1406 are interdigitated with odd wordlines 1407 in a comb structure as illustrated.

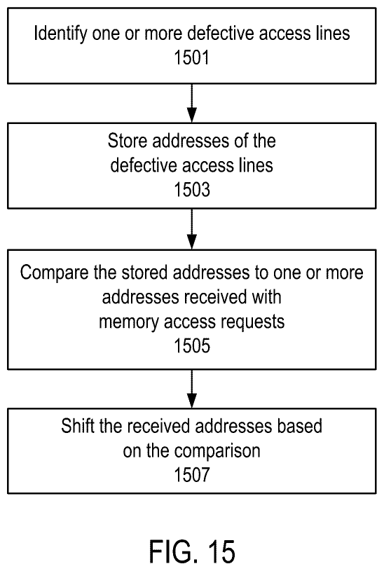

FIG. 15 shows a method for shifting addresses after identifying defective access lines, in accordance with some embodiments. For example, the method of FIG. 15 can be implemented in the system of FIG. 1.

The method of FIG. 15 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method of FIG. 15 is performed at least in part by one or more processing devices (e.g., controller 120 of FIG. 1).

Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At block 1501, one or more defective access lines are identified. In other cases, other types of defects can be identified and associated with particular access lines and/or memory cells. In one example, line 904 is identified as having a broken portion. In one example, defects are identified as being associated with broken addresses 1, 2.

At block 1503, addresses of the defective access lines are stored. In one example, the addresses are stored in list 107.

At block 1505, the stored addresses are compared to one or more addresses received with memory access requests. In one example, this comparison is performed using groups of logic 1010, 1012.

At block 1507, the received addresses are shifted based on the comparison. In one example, this shifting is performed using multiplexers 1030, 1032. In one example, this shifting causes some of redundant tiers in FIG. 13 to be used to replace defective tiers.

In various embodiments, repairs of defective lines by using redundant lines can be done during manufacturing and/or during operation of a memory device. If repairs are performed during operation, the repairs are performed under control of a controller.

In some aspects, the techniques described herein relate to an apparatus (e.g., two or three-dimensional memory device) including: a memory array including access lines (e.g., lines at physical addresses mapped from logical addresses 0, 1, 2, 3 of FIG. 9) including at least one redundant access line (e.g., line x of FIG. 9-—not used); and at least one controller or logic configured to: identify a first access line that is defective (e.g., line 904 at physical address mapped from logical address 2); and in response to identifying that the first access line is defective, change addressing of the first access line to disable use (e.g., change physical address mapped from logical address 2 to x-so that line 904 is not used), change addressing of the redundant access line to enable use (e.g., change physical address mapped for the redundant access line 906x to map from logical address 3), and change addressing of a second access line to continue use (e.g., change physical address mapped from logical address 2 to access line 905).

In some aspects, the techniques described herein relate to an apparatus, wherein the access lines include at least one of wordlines, bitlines, or gate lines.

In some aspects, the techniques described herein relate to an apparatus, wherein the controller is further configured to store addresses for access lines that are identified as defective, and to compare the stored addresses to addresses for access requests received from a host.

In some aspects, the techniques described herein relate to an apparatus, wherein addressing for the first access line is changed to an immediately neighboring access line (e.g., physical addressing for logical address 2 is shifted by one line to the left or right, or shifted by one tier vertically up or down).

In some aspects, the techniques described herein relate to an apparatus, wherein addresses for access lines located on one side of the first access line are each shifted by a fixed value (e.g., addresses for lines on the right side shifted by +1, or addresses for lines on the left side shifted by −1).

In some aspects, the techniques described herein relate to an apparatus, wherein the second access line is located between the first access line and the redundant access line.

In some aspects, the techniques described herein relate to an apparatus, wherein after changing addressing of the first access line to disable use, the redundant access line and the second access line are used for performing a read or write access.

In some aspects, the techniques described herein relate to an apparatus, wherein a third access line and the redundant access line are located on opposite sides of the first access line, and addressing of the third access line is not changed in response to identifying that the first access line is defective.

In some aspects, the techniques described herein relate to an apparatus including: a plurality of access lines; and at least one controller or logic configured to: identify a defective access line; store a first address (e.g., broken address) (e.g., 6) of the defective access line; compare a second address (e.g., a natural address) (e.g., 7) to the first address, wherein the second address is received for a memory access; and based on the comparison, shift the second address (e.g., shift by +1 from 7 to 8 because the natural address 7 is greater than or equal to the broken address 6).

In some aspects, the techniques described herein relate to an apparatus, wherein the access lines include a redundant access line, and use of the defective access line is replaced by use of the redundant access line.

In some aspects, the techniques described herein relate to an apparatus, wherein the defective access line is a first defective access line, the second address (e.g., 100) is shifted by a fixed value (e.g., +1) to a third address (e.g., from 100 to 101), and the controller is further configured to: store a fourth address (e.g., 90) of a second defective access line; compare the third address to the fourth address; and based on comparing the third address to the fourth address, shift the third address by the fixed value (e.g., shift from 101 to 102 because 101 is greater than or equal to 90).

In some aspects, the techniques described herein relate to an apparatus, wherein the fixed value is a positive value (e.g., +1), and the fourth address (e.g., 90) is greater than the first address (e.g., 6).

In some aspects, the techniques described herein relate to an apparatus, wherein stored addresses of defective access lines are compared to addresses received as part of access requests, and the addresses of the defective access lines are compared in a sequential order of increasing or decreasing address (e.g., a broken address of 6 is compared to a received natural address and then shifted before comparing a broken address of 90 to the shifted natural address).

In some aspects, the techniques described herein relate to an apparatus, further including a comparator configured to compare the second address to the first address.

In some aspects, the techniques described herein relate to an apparatus, further including a multiplexer having the second address as a first input and the shifted second address as a second input, wherein the multiplexer is configured to receive a signal from the comparator to select either the first or second input.

In some aspects, the techniques described herein relate to an apparatus including: a plurality of arrangements each having access lines that extend horizontally and are stacked vertically (e.g., as stacks of wordline tiers), wherein the access lines in a first arrangement have increasing addresses in a first vertical direction (e.g., upward), and the access lines in a second arrangement have decreasing addresses in a second vertical direction (e.g., downward) that is opposite to the first vertical direction; and at least one controller or logic configured to shift mapping of addressing for the access lines in at least one arrangement in response to detecting at least one defective access line.

In some aspects, the techniques described herein relate to an apparatus, wherein shifting the mapping includes increasing or decreasing addresses for at least a portion of the access lines in the first and second arrangements, and wherein each address is increased or decreased by a fixed value (e.g., as shown in FIG. 13, tier address 9 shifted by +1 to tier address 10, tier address 10 shifted by +1 to tier address 11).

In some aspects, the techniques described herein relate to an apparatus, wherein shifting the mapping includes mapping addressing for two or more active tiers of access lines to two or more redundant tiers of access lines (e.g., mapping tier address 31 to tier x).

In some aspects, the techniques described herein relate to an apparatus, wherein the defective access line has a first address, and shifting the mapping includes shifting addresses of access lines located on one side of (e.g., greater than) the first address, but not shifting addresses of access lines located on the other side of (e.g., less than) the first address.

In some aspects, the techniques described herein relate to an apparatus, wherein shifting the mapping is based on a difference between an electrical distance from a driver to a memory cell associated with the defective access line and an electrical distance from the driver to a memory cell associated with an access line that replaces the defective access line (e.g., shift physical addressing from the defective access line to the closest available access line in a consecutive addressing order to minimize the change in electrical distance from a driver to memory cells being accessed) (e.g., controller selects a change in mapping to minimize the change in electrical distance).

The disclosure includes various devices which perform the methods and implement the systems described above, including data processing systems which perform these methods, and computer-readable media containing instructions which when executed on data processing systems cause the systems to perform these methods.

The description and drawings are illustrative and are not to be construed as limiting. Numerous specific details are described to provide a thorough understanding. However, in certain instances, well-known or conventional details are not described in order to avoid obscuring the description. References to one or an embodiment in the present disclosure are not necessarily references to the same embodiment; and, such references mean at least one.

As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

Reference in this specification to “one embodiment” or “an embodiment” means that a particular feature, structure, or characteristic described in connection with the embodiment is included in at least one embodiment of the disclosure. The appearances of the phrase “in one embodiment” in various places in the specification are not necessarily all referring to the same embodiment, nor are separate or alternative embodiments mutually exclusive of other embodiments. Moreover, various features are described which may be exhibited by some embodiments and not by others. Similarly, various requirements are described which may be requirements for some embodiments but not other embodiments.

In this description, various functions and/or operations may be described as being performed by or caused by software code to simplify description. However, those skilled in the art will recognize what is meant by such expressions is that the functions and/or operations result from execution of the code by one or more processing devices, such as a microprocessor, Application-Specific Integrated Circuit (ASIC), graphics processor, and/or a Field-Programmable Gate Array (FPGA). Alternatively, or in combination, the functions and operations can be implemented using special purpose circuitry (e.g., logic circuitry), with or without software instructions. Embodiments can be implemented using hardwired circuitry without software instructions, or in combination with software instructions. Thus, the techniques are not limited to any specific combination of hardware circuitry and software, nor to any particular source for the instructions executed by a computing device.

While some embodiments can be implemented in fully functioning computers and computer systems, various embodiments are capable of being distributed as a computing product in a variety of forms and are capable of being applied regardless of the particular type of computer-readable medium used to actually effect the distribution.

At least some aspects disclosed can be embodied, at least in part, in software. That is, the techniques may be carried out in a computing device or other system in response to its processing device, such as a microprocessor, executing sequences of instructions contained in a memory, such as ROM, volatile RAM, non-volatile memory, cache or a remote storage device.

Routines executed to implement the embodiments may be implemented as part of an operating system, middleware, service delivery platform, SDK (Software Development Kit) component, web services, or other specific application, component, program, object, module or sequence of instructions (sometimes referred to as computer programs). Invocation interfaces to these routines can be exposed to a software development community as an API (Application Programming Interface). The computer programs typically comprise one or more instructions set at various times in various memory and storage devices in a computer, and that, when read and executed by one or more processors in a computer, cause the computer to perform operations necessary to execute elements involving the various aspects.

A computer-readable medium can be used to store software and data which when executed by a computing device causes the device to perform various methods. The executable software and data may be stored in various places including, for example, ROM, volatile RAM, non-volatile memory and/or cache. Portions of this software and/or data may be stored in any one of these storage devices. Further, the data and instructions can be obtained from centralized servers or peer to peer networks. Different portions of the data and instructions can be obtained from different centralized servers and/or peer to peer networks at different times and in different communication sessions or in a same communication session. The data and instructions can be obtained in entirety prior to the execution of the applications. Alternatively, portions of the data and instructions can be obtained dynamically, just in time, when needed for execution. Thus, it is not required that the data and instructions be on a computer-readable medium in entirety at a particular instance of time.

Examples of computer-readable media include, but are not limited to, recordable and non-recordable type media such as volatile and non-volatile memory devices, read only memory (ROM), random access memory (RAM), flash memory devices, solid-state drive storage media, removable disks, magnetic disk storage media, optical storage media (e.g., Compact Disk Read-Only Memory (CD ROMs), Digital Versatile Disks (DVDs), etc.), among others. The computer-readable media may store the instructions. Other examples of computer-readable media include, but are not limited to, non-volatile embedded devices using NOR flash or NAND flash architectures. Media used in these architectures may include un-managed NAND devices and/or managed NAND devices, including, for example, eMMC, SD, CF, UFS, and SSD.

In general, a non-transitory computer-readable medium includes any mechanism that provides (e.g., stores) information in a form accessible by a computing device (e.g., a computer, mobile device, network device, personal digital assistant, manufacturing tool having a controller, any device with a set of one or more processors, etc.). A “computer-readable medium” as used herein may include a single medium or multiple media (e.g., that store one or more sets of instructions).

In various embodiments, hardwired circuitry may be used in combination with software and firmware instructions to implement the techniques. Thus, the techniques are neither limited to any specific combination of hardware circuitry and software nor to any particular source for the instructions executed by a computing device.

Various embodiments set forth herein can be implemented using a wide variety of different types of computing devices. As used herein, examples of a “computing device” include, but are not limited to, a server, a centralized computing platform, a system of multiple computing processors and/or components, a mobile device, a user terminal, a vehicle, a personal communications device, a wearable digital device, an electronic kiosk, a general purpose computer, an electronic document reader, a tablet, a laptop computer, a smartphone, a digital camera, a residential domestic appliance, a television, or a digital music player. Additional examples of computing devices include devices that are part of what is called “the internet of things” (IoT). Such “things” may have occasional interactions with their owners or administrators, who may monitor the things or modify settings on these things. In some cases, such owners or administrators play the role of users with respect to the “thing” devices. In some examples, the primary mobile device (e.g., an Apple iPhone) of a user may be an administrator server with respect to a paired “thing” device that is worn by the user (e.g., an Apple watch).

In some embodiments, the computing device can be a computer or host system, which is implemented, for example, as a desktop computer, laptop computer, network server, mobile device, or other computing device that includes a memory and a processing device. The host system can include or be coupled to a memory sub-system so that the host system can read data from or write data to the memory sub-system. The host system can be coupled to the memory sub-system via a physical host interface. In general, the host system can access multiple memory sub-systems via a same communication connection, multiple separate communication connections, and/or a combination of communication connections.

In some embodiments, the computing device is a system including one or more processing devices. Examples of the processing device can include a microcontroller, a central processing unit (CPU), special purpose logic circuitry (e.g., a field programmable gate array (FPGA), an application specific integrated circuit (ASIC), etc.), a system on a chip (SoC), or another suitable processor.

In one example, a computing device is a controller of a memory system. The controller includes a processing device and memory containing instructions executed by the processing device to control various operations of the memory system.

Although some of the drawings illustrate a number of operations in a particular order, operations which are not order dependent may be reordered and other operations may be combined or broken out. While some reordering or other groupings are specifically mentioned, others will be apparent to those of ordinary skill in the art and so do not present an exhaustive list of alternatives. Moreover, it should be recognized that the stages could be implemented in hardware, firmware, software or any combination thereof.

In the foregoing specification, the disclosure has been described with reference to specific exemplary embodiments thereof. It will be evident that various modifications may be made thereto without departing from the broader spirit and scope as set forth in the following claims. The specification and drawings are, accordingly, to be regarded in an illustrative sense rather than a restrictive sense.

1. An apparatus comprising:
a memory array comprising access lines including at least one redundant access line; and
at least one controller or logic configured to:
based on stored data identifying that a first access line is defective, change physical addressing of the first access line to disable use, change physical addressing of the redundant access line to enable use, and change physical addressing of a second access line to continue use.

2. The apparatus of claim 1, wherein the access lines comprise at least one of wordlines, bitlines, or gate lines.

3. The apparatus of claim 1, wherein the controller or logic is further configured to:
map, using a logical-to-physical mapping table, logical addresses received in an access request from a host to first physical addresses; and
compare a stored list of physical addresses for access lines that are identified as defective to the first physical addresses.

4. The apparatus of claim 1, wherein logical-to-physical address mapping of a logical address of an incoming access request is shifted from a first physical address of the first access line to a second physical address of an immediately neighboring access line.

5. The apparatus of claim 1, wherein addresses for access lines located on one side of the first access line are each shifted by a fixed value.

6. The apparatus of claim 1, wherein the second access line is located between the first access line and the redundant access line.

7. The apparatus of claim 1, wherein after changing addressing of the first access line to disable use, the redundant access line and the second access line are each enabled for use during a corresponding read or write access.

8. The apparatus of claim 1, wherein a third access line and the redundant access line are located on opposite sides of the first access line, and addressing of the third access line is not changed in response to identifying that the first access line is defective.

9. An apparatus comprising:
a plurality of access lines; and
at least one controller or logic configured to:
compare a second address to a stored first address of a defective access line, wherein the second address corresponds to a memory access request; and
based on the comparison, shift the second address.

10. The apparatus of claim 9, wherein the access lines include a redundant access line, and use of the defective access line during memory accesses is replaced by use of the redundant access line, and wherein the redundant access line has an address different than an address of the defective access line.

11. The apparatus of claim 9, wherein the defective access line is a first defective access line, the second address is shifted by a fixed value to a third address, a fourth address of a second defective access line is stored in a list, and the controller or logic is further configured to:
compare, using the list, the third address to the fourth address; and
based on comparing the third address to the fourth address, shift the third address by the fixed value.

12. The apparatus of claim 11, wherein the fixed value is a positive value, and the fourth address is greater than the first address.

13. The apparatus of claim 9, wherein stored physical addresses of defective access lines are compared to first physical addresses mapped from logical addresses received as part of access requests, and the stored physical addresses of the defective access lines are compared in a sequential order of increasing or decreasing address.

14. The apparatus of claim 9, further comprising a comparator configured to compare the second address to the first address.

15. The apparatus of claim 14, further comprising a multiplexer having the second address as a first input and the shifted second address as a second input, wherein the multiplexer is configured to receive a signal from the comparator to select either the first or second input.

16. An apparatus comprising:
a plurality of arrangements each having access lines that extend horizontally and are stacked vertically, wherein the access lines in a first arrangement have increasing addresses in a first vertical direction, and the access lines in a second arrangement have decreasing addresses in a second vertical direction that is opposite to the first vertical direction; and
at least one controller or logic configured to shift mapping of addressing for the access lines in at least one arrangement based on stored data regarding at least one defective access line.

17. The apparatus of claim 16, wherein shifting the mapping comprises increasing or decreasing addresses for at least a portion of the access lines in the first and second arrangements, and wherein each address is increased or decreased by a fixed value.

18. The apparatus of claim 16, wherein shifting the mapping comprises mapping addressing for two or more active tiers of access lines to two or more redundant tiers of access lines.

19. The apparatus of claim 16, wherein the defective access line has a first address, and shifting the mapping comprises shifting addresses of access lines located on one side of the first address, but not shifting addresses of access lines located on the other side of the first address.

20. The apparatus of claim 16, wherein shifting the mapping is based on a difference between an electrical distance from a driver to a memory cell associated with the defective access line and an electrical distance from the driver to a memory cell associated with an access line that replaces the defective access line.

21. An apparatus comprising:
a plurality of access lines; and
at least one controller or logic configured to:
compare a second physical address to a first physical address, wherein the first address is a stored address in a list of defective access lines, and the second address is received from a host for a memory access; and
based on the comparison, shift the second address.

22. The apparatus of claim 21, wherein the access lines include a redundant access line having an address different than an address of the defective access line, and further use of the defective access line is disabled.

23. The apparatus of claim 21, wherein the defective access line is a first defective access line, the second address is shifted by a fixed value to a third address, and the controller or logic is further configured to:
compare the third address to a stored fourth address of a second defective access line; and
based on comparing the third address to the fourth address, shift the third address by the fixed value.

24. The apparatus of claim 23, wherein the fixed value is a positive value, and the fourth address is greater than the first address.

25. The apparatus of claim 21, wherein stored addresses of defective access lines are compared to addresses received as part of access requests, and the addresses of the defective access lines are compared in a sequential order of increasing or decreasing address.

26. The apparatus of claim 21, further comprising a comparator configured to compare the second address to the first address.

27. The apparatus of claim 26, further comprising a multiplexer having the second address as a first input and the shifted second address as a second input, wherein the multiplexer is configured to receive a signal from the comparator to select either the first or second input.

28. The apparatus of claim 21, wherein the controller or logic is further configured to, in response to identifying the defective access line, store the first address of the defective access line.
